(19) United States
(12) Patent Application Publication
(10) Pub. No.: US 2026/0275125 A1
(43) Pub. Date: Sep. 17, 2026

(54) COMPOSITION, METHOD OF PREPARING FINE PATTERN BY USING THE SAME, AND METHOD OF MANUFACTURING SEMICONDUCTOR DEVICE BY USING THE SAME

(71) Applicant: Samsung Electronics Co., Ltd., Suwon-si (KR)

(72) Inventors: Wonsik YOON, Suwon-si (KR); Giho Ko, Suwon-si (KR); Youngchan Kim, Suown-si (KR); Jina Kim, Suwon-si (KR); Jeongil Park, Suwon-si (KR); Minhyung Cho, Suwon-si (KR); Donghoon Ha, Suwon-si (KR); Cheol Ham, Suwon-si (KR); Kyuyoung Hwang, Suwon-si (KR)

(73) Assignee: Samsung Electronics Co., Ltd., Suwon-si (KR)

(21) Appl. No.: 19/441,161

(22) Filed: Jan. 6, 2026

(30) Foreign Application Priority Data
Mar. 11, 2025 (KR) 10-2025-0031663

(51) Int. Cl. C09D 5/24; C09D 7/20; H10W 20/00; H10W 20/42; H10W 20/44; H10W 20/48

(52) U.S. Cl. CPC C09D 5/24; C09D 7/20; H10W 20/056; H10W 20/0765; H10W 20/42; H10W 20/4405; H10W 20/4421; H10W 20/4432; H10W 20/4441; H10W 20/48

(57) ABSTRACT

Provided are a composition including a solvent and a protection layer-forming material, a method of preparing a fine pattern by using the same, and a method of manufacturing a semiconductor device by using the same. The protection layer-forming material may include a compound represented by Formula 1 below:

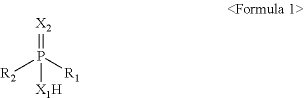

For descriptions of Formula 1, refer to the specification.

### CROSS-REFERENCE TO RELATED APPLICATION

This application is based on and claims priority under 35 U.S.C. § 119 to Korean Patent Application No. 10-2025-0031663, filed on Mar. 11, 2025, in the Korean Intellectual Property Office, the disclosure of which is incorporated by reference herein in its entirety.

### BACKGROUND

### 1. Field

The disclosure relates to a composition, a method of preparing a fine pattern by using the same, and a method of manufacturing a semiconductor device by using the same.

### 2. Description of the Related Art

With the advancement of electronic technologies, down-scaling of semiconductor devices has recently been accelerated, creating demand for higher integration density and reduced power consumption in semiconductor chips. As a result, spaces between circuit components such as wirings are gradually decreasing, and resistance between the wirings and vias is increasing. Research is being conducted to reduce resistance between wirings and vias to improve the reliability of semiconductor devices.

### SUMMARY

Provided are a composition including a protection layer-forming material capable of forming a protection layer having improved or excellent thermal stability and/or hydrophobicity selectively on a surface of a particular material without generating residual aggregated particles with a relatively large particle size, a method of preparing a fine pattern by using the same, and a method of manufacturing a semiconductor device using the same.

Additional aspects will be set forth in part in the description which follows and, in part, will be apparent from the description, or may be learned by practice of the presented embodiments of the disclosure.

According to an embodiment of the disclosure, a composition may include:
a solvent and a protection layer-forming material,
where the protection layer-forming material may include a compound represented by Formula 1 below:

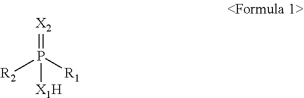

wherein in Formula 1,
X₁ and X₂ each independently may be O or S,
R₁ and R₂ each independently may be a C₁-C₃₀alkyl group, a C₂-C₃₀alkenyl group, a C₃-C₁₀cycloalkyl group, a C₂-C₁₀ heterocycloalkyl group, a C₆-C₃₀ aryl group, or a C₂-C₃₀ heteroaryl group,
wherein, in R₁ and R₂, at least one hydrogen optionally may be substituted with a halogen atom, a C₁-C₃₀alkyl group, *—O(Q₁), *—NH₂, *—NH(Q₁), or *—N(Q₁)(Q₂),
wherein Q₁ and Q₂ each independently may be a C₁-C₃₀alkyl group, or a C₆-C₃₀ aryl group,
wherein, in Q₁ and Q₂, at least one hydrogen optionally may be substituted with a halogen atom, a C₁-C₃₀alkyl group, a C₁-C₃₀alkoxy group, an amino group, a (C₁-C₁₀alkyl)amino group, or a di(C₁-C₁₀alkyl)amino group, and
* is a bonding site with a neighboring atom.

According to an embodiment of the disclosure, a method of preparing a fine pattern may include:
preparing a substrate having a first layer and a second layer on the substrate, wherein the first layer may include a metal and the second layer may include an insulating material,
applying the composition onto the first layer, and
heat treating the composition to form a protection layer pattern on a surface of the first layer, the protection layer pattern exposing a surface of the second layer.

In some embodiments, the method of preparing a fine pattern may further include:
applying a third layer pattern-forming material onto the first layer on which the protection layer pattern is formed and the second layer,
removing the protection layer pattern to form a third layer pattern on the surface of the second layer, the third layer pattern having an opening exposing the surface of the first layer, and
applying a fourth layer onto a surface of the third layer pattern and the surface of the first layer.

According to an example embodiment of the disclosure, a method of manufacturing a semiconductor device may include:
providing a substrate including an interlayer insulating layer on the substrate and a via in a via trench defined by the interlayer insulating layer, the interlayer insulating layer defining a wiring trench over the via trench and exposing the via in the via trench, a surface of the via (or, an exposed via) being in fluid communication with the wiring trench;
applying a composition into the wiring trench, the composition including a solvent and a protection layer-forming material, wherein the protection layer-forming material may include a compound represented by Formula 1 below;
heat treating the composition to form a protection layer pattern on the surface of the via, the protection layer pattern exposing a surface of the interlayer insulating layer, the protection layer pattern being formed in the wiring trench;
applying a wiring barrier layer pattern-forming material into the wiring trench;
removing the protection layer pattern to form a wiring barrier layer pattern on the surface of the interlayer insulating layer, the wiring barrier layer pattern including an opening that exposes the surface of the via, and
forming a wiring pattern by applying a wiring filling layer onto the surface of the wiring barrier layer pattern and the surface of the via, the wiring pattern being inside the wiring trench,

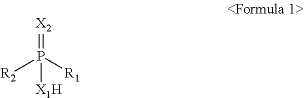

wherein, in Formula 1,
X₁ and X₂ each independently may be O or S, and
R₁ and R₂ each independently may be a C₁-C₃₀alkyl group, a C₂-C₃₀alkenyl group, a C₃-C₁₀ cycloalkyl group, a C₂-C₁₀ heterocycloalkyl group, a C₆-C₃₀ aryl group, or a C₂-C₃₀ heteroaryl group,
wherein, in R₁ and R₂, at least one hydrogen optionally may be substituted with a halogen atom, a C₁-C₃₀alkyl group, *—O(Q₁), *—NH₂, *—NH(Q₁), or *—N(Q₁)(Q₂),
wherein Q₁ and Q₂ each may be independently a C₁-C₃₀alkyl group, or a C₆-C₃₀ aryl group,
wherein, in Q₁ and Q₂, at least one hydrogen optionally may be substituted with a halogen atom, a C₁-C₃₀alkyl group, a C₁-C₃₀alkoxy group, an amino group, a (C₁-C₁₀alkyl)amino group, or a di(C₁-C₁₀alkyl)amino group, and
* may be a bonding site with a neighboring atom.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A to 1E are views for schematically describing a method of preparing a fine pattern according to an embodiment; and

FIGS. 2A to 2E are views for schematically describing a method of manufacturing a semiconductor device.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

### Composition

The composition may include a solvent and a protection layer-forming material.

The composition may be used for a method of preparing a fine pattern disclosed in the specification.

According to an embodiment, the composition may not include an oxidant.

According to an embodiment, the composition may further include a pH adjuster, for example, tetramethylammonium hydroxide (TMAH).

The solvent may be miscible with the protection layer-forming material or may dissolve the protection layer-forming material serving as a matrix delivering the protection layer-forming material.

According to an embodiment, the solvent may include one type of compound or two or more different types of compounds.

According to another embodiment, the solvent may be a polar solvent.

According to another embodiment, the solvent may include a compound having a dielectric constant of 15 or more or 20 or more. For example, the solvent may include a compound having a dielectric constant of about 15 to about 100, about 15 to about 90, about 15 to about 80, about 20 to about 100, about 20 to about 90, or about 20 to about 80. By including the compound having a dielectric constant satisfying the above-described ranges, the solvent may effectively be mixed with the protection layer-forming material, which will be described below.

According to another embodiment, the solvent may include water, a water-miscible compound, or any combination thereof. The water-miscible compound may be a compound other than water and miscible with or dissolved in water.

According to another embodiment, the solvent may include water and at least one water-miscible compound. In this regard, a weight ratio of water to the at least one water-miscible compound may be about 10:90 to about 40:60.

According to another embodiment, the solvent may include water, sulfolane, an alcohol (e.g., monohydric alcohol, dihydric alcohol, and trihydric alcohol), acetone, ethyl lactate, propylene glycol methyl ether acetate (PGMEA), propylene glycol methyl ether (PGME), methyl isobutyl ketone (MIBK), N-methyl-2-pyrrolidone (NMP), dimethyl sulfoxide (DMSO), dimethylformamide (DMF), or any combination thereof.

Examples of the monohydric alcohol may include methanol, ethanol, propanol, and butanol.

Examples of the dihydric alcohol may include ethylene glycol and propylene glycol.

According to an embodiment, the solvent may include water, sulfolane, and an alcohol (e.g., ethylene glycol).

The protection layer-forming material may include a compound represented by Formula 1 below.

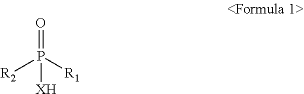

In Formula 1,
X₁ and X₂ are each independently O or S, and
R₁ and R₂ are each independently a C₁-C₃₀alkyl group (e.g., C₁-C₂₀alkyl group or C₁-C₁₀alkyl group), a C₂-C₃₀alkenyl group (e.g., C₂-C₂₀alkenyl group or C₂-C₁₀alkenyl group), a C₃-C₁₀cycloalkyl group (e.g., C₅-C₇ cycloalkyl group), a C₂-C₁₀ heterocycloalkyl group (e.g., C₃-C₄ heterocycloalkyl group), a C₆-C₃₀ aryl group (e.g., C₆-C₁₀ aryl group), or a C₂-C₃₀ heteroaryl group (e.g., C₂-C₁₀ heteroaryl group), wherein at least one hydrogen of the C₁-C₃₀alkyl group, at least one hydrogen of the C₂-C₃₀alkenyl group, at least one hydrogen of the C₃-C₁₀cycloalkyl group, at least one hydrogen of the C₂-C₁₀ heterocycloalkyl group, at least one hydrogen of the C₆-C₃₀ aryl group, at least one hydrogen of the C₂-C₃₀ heteroaryl group, or any combination thereof may optionally be substituted with a halogen atom, a C₁-C₃₀alkyl group (e.g., C₁-C₁₀alkyl group), *—O(Q₁), *—NH₂, *—NH(Q₁), or *—N(Q₁)(Q₂),
wherein Q₁ and Q₂ are each independently a C₁-C₃₀alkyl group (e.g., C₁-C₁₀alkyl group) or a C₆-C₃₀ aryl group (e.g., C₆-C₁₀ aryl group), wherein at least one hydrogen of the C₁-C₃₀alkyl group, at least one hydrogen of the C₆-C₃₀ aryl group, or combination thereof may optionally substituted with a halogen atom, a C₁-C₃₀alkyl group (e.g., C₁-C₁₀alkyl group), a C₁-C₃₀alkoxy group (e.g., C₁-C₁₀alkoxy group), an amino group, a (C₁-C₁₀alkyl)amino group, or a di(C₁-C₁₀alkyl)amino group, and
* is a bonding site with a neighboring atom.

The compound represented by Formula 1 may chemically bind to a surface atom of a certain material (e.g., metal) to form a protection layer, but cannot chemically bind to a surface atom of another material (e.g., insulating material) failing to formation of a protection layer. That is, the compound represented by Formula 1 is a substance that selectively forms a protection layer according to a material in contact therewith. Therefore, the protection layer-forming material including the compound represented by Formula 1 may also be referred to as “selective protection layer-forming material”.

According to an embodiment, the compound represented by Formula 1 may form a self-assembled monolayer (SAM) including a moiety represented by Formula 1A below on a surface of the certain material (e.g., metal).

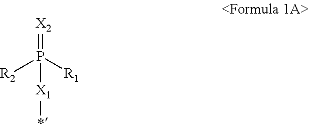

In Formula 1A,
X₁, X₂, R₁, and R₂ are as described above in the description of Formula 1 of the specification, and
*′ is a bonding site (e.g., chemical bonding site) with an atom of the surface of the certain material such as metal atom.

Throughout the specification, the C₁-C₃₀alkyl group, the C₁-C₂₀alkyl group, the C₁-C₁₀alkyl group, the C₃-C₃₀alkyl group, the C₅-C₂₀alkyl group, the C₂-C₃₀alkenyl group, and the C₂-C₂₀alkenyl group may each independently be linear or branched.

As used herein, the C₃-C₁₀cycloalkyl group may be, for example, a cyclobutyl group, a cyclopentyl group, a cyclohexyl group, a cycloheptyl group, or a cyclooctyl group.

As used herein, the C₂-C₁₀ heterocycloalkyl group may be, for example, a tetrahydrofuranyl group or a tetrahydrothiophenyl group.

As used herein, the C₆-C₃₀ aryl group may be, for example, a phenyl group, a naphthyl group, a phenanthrenyl group, an anthracenyl group, or a fluorenyl group.

As used herein, the C₂-C₃₀ heteroaryl group may be, for example, a pyridinyl group, a pyrimidinyl group, a pyrazinyl group, a pyridazinyl group, a triazinyl group, or a carbazolyl group.

As used herein, the C₁-C₃₀alkoxy group and the C₁-C₁₀alkoxy group may be represented by *—O(Q₁), wherein Q₁₁ is a C₁-C₃₀alkyl group or a C₁-C₁₀alkyl group.

According to an embodiment, in Formulae 1 and 1A, X₁ and X₂ may each independently be O.

According to another embodiment, in Formulae 1 and 1A, X₁ may be S and X₂ may be O.

According to another embodiment, in Formulae 1 and 1A, X₁ may be O and X₂ may be S.

According to another embodiment, in Formulae 1 and 1A, X₁ and X₂ may each independently be S.

According to another embodiment, in Formulae 1 and 1A,
R₁ and R₂ may each independently be a C₁-C₂₀alkyl group, a C₂-C₂₀alkenyl group, a C₅-C₇ cycloalkyl group, a C₃-C₄ heterocycloalkyl group, a C₆-C₁₀ aryl group, or a C₂-C₁₀ heteroaryl group, wherein at least one hydrogen of the C₁-C₂₀alkyl group, at least one hydrogen of the C₂-C₂₀alkenyl group, at least one hydrogen of the C₅-C₇ cycloalkyl group, at least one hydrogen of the C₃-C₄ heterocycloalkyl group, at least one hydrogen of the C₆-C₁₀ aryl group, at least one hydrogen of the C₂-C₁₀ heteroaryl group, or any combination thereof may optionally be substituted with a halogen atom, a C₁-C₁₀alkyl group, *—O(Q₁), *—NH₂, *—NH(Q₁), or *—N(Q₁)(Q₂),
wherein Q₁ and Q₂ may each independently be a C₁-C₁₀alkyl group or a C₆-C₁₀ aryl group, wherein at least one hydrogen of the C₁-C₁₀alkyl group, at least one hydrogen of the C₆-C₁₀ aryl group, or combination thereof may optionally be substituted with a halogen atom, a C₁-C₁₀alkyl group, a C₁-C₁₀alkoxy group, an amino group, a (C₁-C₁₀alkyl)amino group, or a di(C₁-C₁₀alkyl)amino group.

According to another embodiment, in Formulae 1 and 1A, R₁ and R₂ may each independently be a C₅-C₂₀alkyl group.

According to another embodiment, in Formulae 1 and 1A, R₁ and R₂ may each independently be a branched C₃-C₃₀alkyl group or a branched C₅-C₂₀alkyl group.

According to another embodiment, in Formulae 1 and 1A, R₁ and R₂ may each independently be a C₁-C₂₀alkyl group, wherein at least one hydrogen of the C₁-C₂₀alkyl group may optionally be substituted with a halogen atom, *—O(Q₁), *—NH₂, *—NH(Q₁), or *—N(Q₁)(Q₂), wherein Q₁ and Q₂ may each independently be a C₁-C₁₀alkyl group, wherein at least one hydrogen of the C₁-C₁₀alkyl group may optionally be substituted with a halogen atom, a C₁-C₁₀alkyl group, a C₁-C₁₀alkoxy group, an amino group, a (C₁-C₁₀alkyl)amino group, or a di(C₁-C₁₀alkyl)amino group.

According to another embodiment, in Formulae 1 and 1A, R₁ and R₂ may each independently be a C₅-C₇ cycloalkyl group (e.g., a cyclopentyl group, a cyclohexyl group, and a cycloheptyl group), a C₃-C₄ heterocycloalkyl group (e.g., a tetrahydrofuranyl group and a tetrahydrothiophenyl group), a C₆-C₁₀ aryl group (e.g., a phenyl group and a naphthyl group), or a C₂-C₁₀ heteroaryl group (e.g., a pyridinyl group, a pyrimidinyl group, a pyrazinyl group, a pyridazinyl group, and a triazinyl group), wherein at least one hydrogen of the C₅-C₇ cycloalkyl group, at least one hydrogen of the C₃-C₄ heterocycloalkyl group, at least one hydrogen of the C₆-C₁₀ aryl group, at least one hydrogen of the C₂-C₁₀ heteroaryl group, or any combination thereof may optionally be substituted with a halogen atom, a C₁-C₁₀alkyl group, *—O(Q₁), *—NH₂, *—NH(Q₁), or *—N(Q₁)(Q₂), wherein Q₁ and Q₂ may each independently be a C₁-C₁₀alkyl group, wherein at least one hydrogen of the C₁-C₁₀alkyl group may optionally be substituted with a halogen atom, a C₁-C₁₀alkyl group, a C₁-C₁₀alkoxy group, an amino group, a (C₁-C₁₀alkyl)amino group, or a di(C₁-C₁₀alkyl)amino group.

According to another embodiment, the number of carbon atoms included in each of R₁ and R₂ in Formulae 1 and 1A may be 4 or more. For example, the number of carbon atoms included in each of R₁ and R₂ in Formulae 1 and 1A may be 4 to 50, 4 to 40, 4 to 30, or 4 to 20.

According to another embodiment, in Formulae 1 and 1A, R₁ and R₂ may each independently be a C₁-C₃₀alkyl group, wherein at least one hydrogen of the C₁-C₃₀alkyl group may optionally be substituted with a halogen atom, a C₁-C₃₀alkyl group, *—O(Q₁), *—NH₂, *—NH(Q₁), or *—N(Q₁)(Q₂) as described in the specification, but the number of carbon atoms included in each of R₁ and R₂ may be 4 or more, 4 to 30, 4 to 20, 5 to 30, 5 to 20, 6 to 30, or 6 to 20.

According to another embodiment, R₁ and R₂ in Formulae 1 and 1A may be identical to each other.

According to another embodiment, R₁ and R₂ in Formulae 1 and 1A may be different from each other.

According to another embodiment, the compound represented by Formula 1 may be one of the compounds shown below.

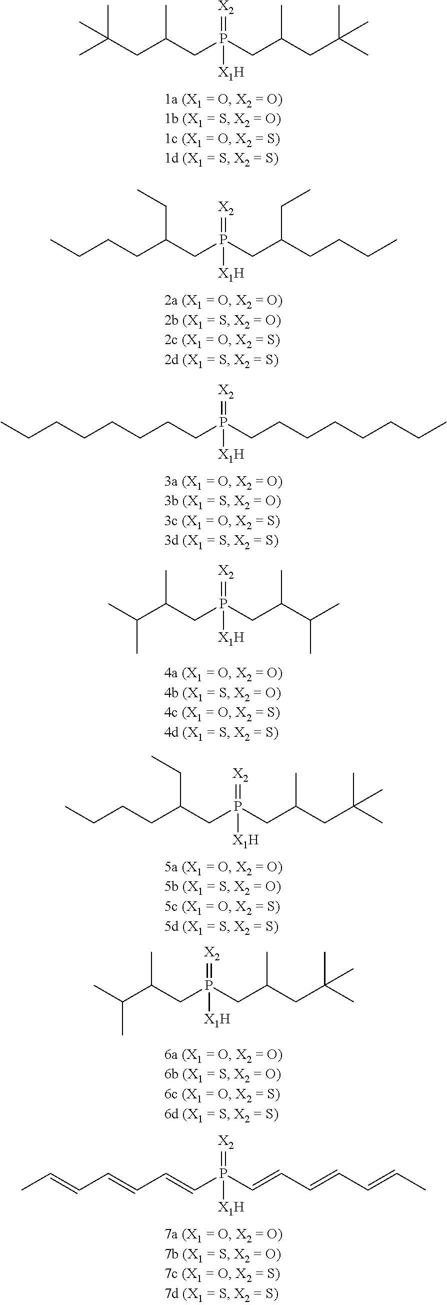

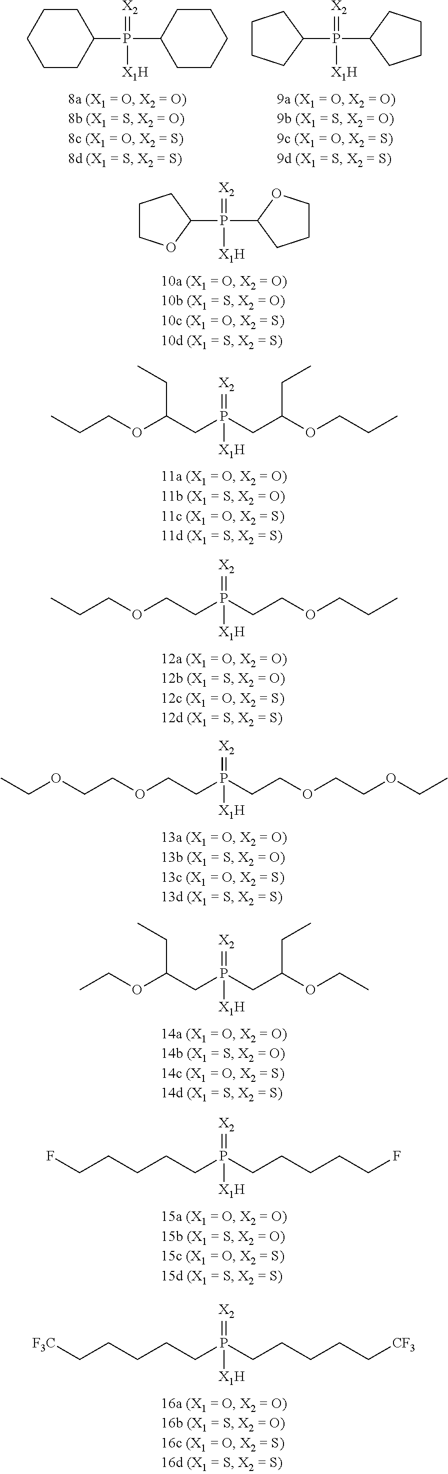

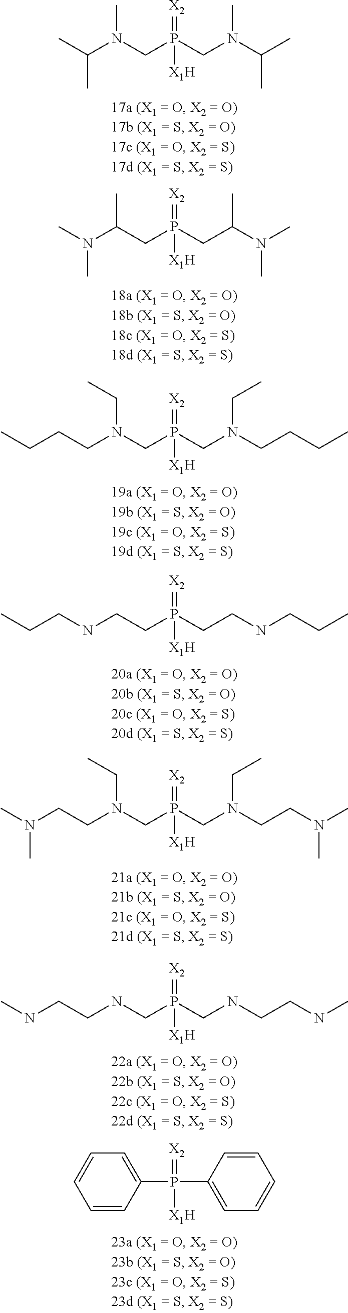

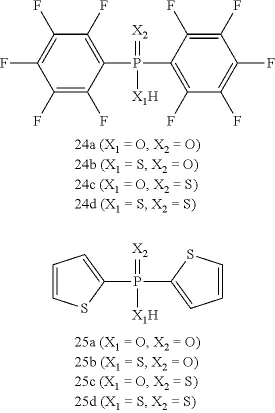

According to another embodiment, the protection layer-forming material may further include a compound represented by Formula 2 below.

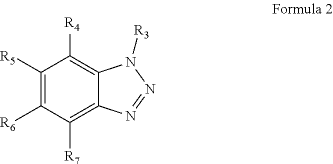

In Formula 2, R₃ to R₇ are each independently hydrogen, a hydroxyl group, an amino group, a nitro group, a C₁-C₃₀alkoxy group, a C₁-C₃₀alkyl group, a C₂-C₃₀alkenyl group, a C₆-C₃₀ aryl group, or a C₂-C₃₀ heteroaryl group.

For example, in Formula 2, R₄ to R₇ (or, R₃ to R₇) may be hydrogen.

An amount of the protection layer-forming material may be about 0.001 wt % to about 10 wt %, about 0.001 wt % to about 5 wt %, about 0.001 wt % to about 1 wt %, about 0.001 wt % to about 0.5 wt %, about 0.001 wt % to about 0.3 wt %, 0.01 wt % to about 10 wt %, about 0.01 wt % to about 5 wt %, about 0.01 wt % to about 1 wt %, about 0.01 wt % to about 0.5 wt %, about 0.01 wt % to about 0.3 wt %, about 0.05 wt % to about 10 wt %, about 0.05 wt % to about 5 wt %, about 0.05 wt % to about 1 wt %, about 0.05 wt % to about 0.5 wt %, about 0.05 wt % to about 0.3 wt %, or about 0.05 wt % to about 0.2 wt %, based on 100 wt % of the composition. In the case where the amount of the protection layer-forming material satisfies the above-described range, the protection layer pattern with an appropriate thickness may be formed.

According to an embodiment, the composition may have a pH of about 5 to about 10, about 6 to about 9, or about 7 to about 8. In the case where the composition satisfies the above-described pH range, etching of the layer on which the protection layer is formed (e.g., a metal layer) may be reduced or minimized.

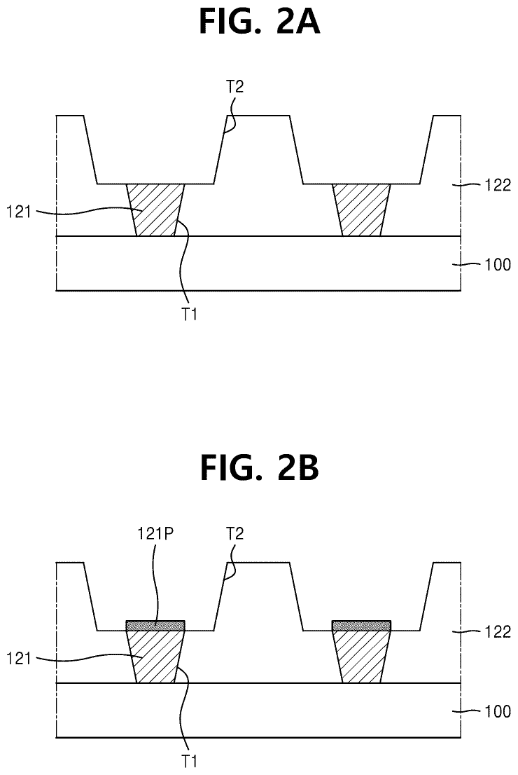

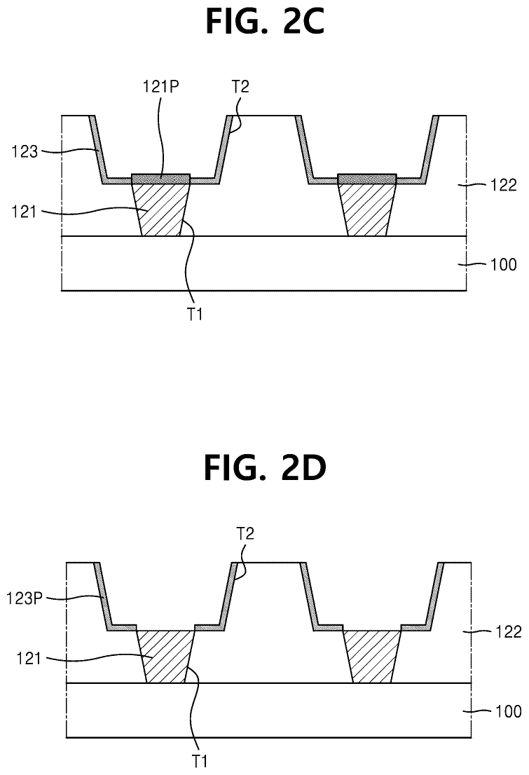

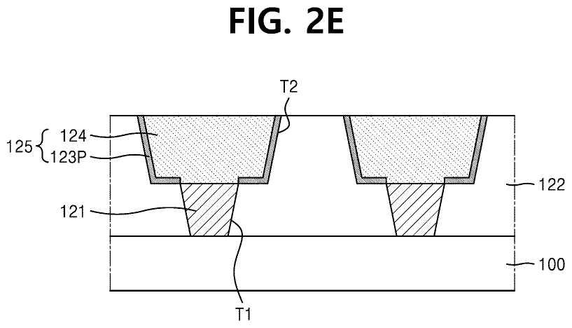

According to another embodiment, the composition may have a viscosity of about 0.1 cP to about 30 cP at 25° C. In the case where the viscosity of the composition satisfies the above-described range, the composition may be effectively applied into a wiring trench T2 having a fine size shown in FIG. 2A which will be described below. Although the embodiment is not limited to a particular theory, a composition with an excessively high viscosity may not arrive at the inner wall of the wiring trench T2 having a fine size shown in FIG. 2A which will be described below.

### Method of Preparing Fine Pattern

The composition may be effectively used in formation of a protection layer pattern in the method of preparing a fine pattern.

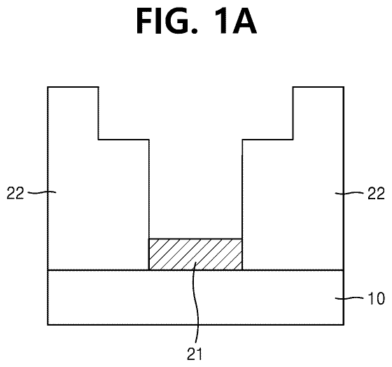

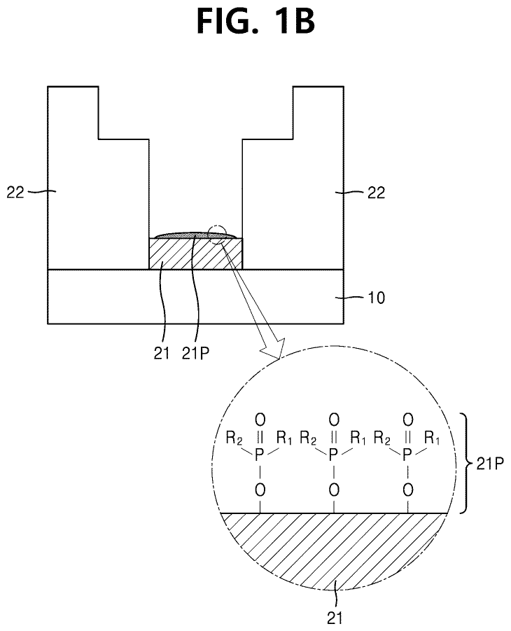

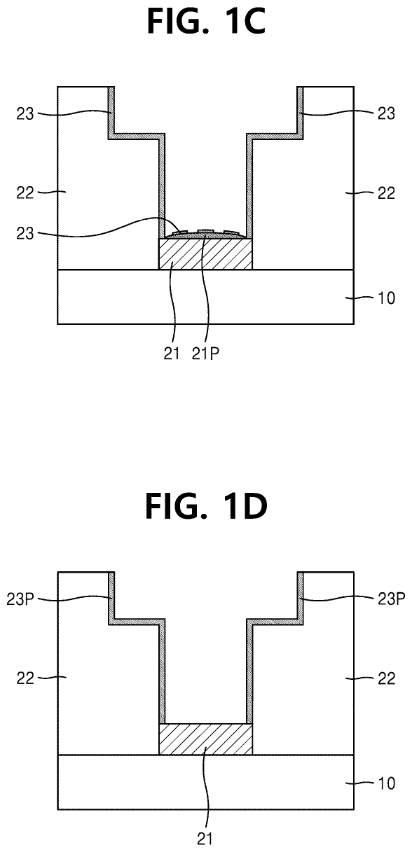

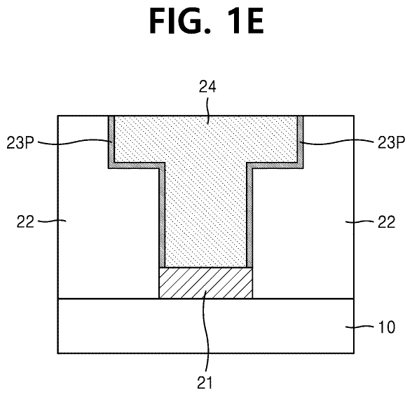

Hereinafter, referring to FIGS. 1A to 1E, a method of preparing a fine pattern using the composition according to an embodiment will be described.

First, as shown in FIG. 1A, a substrate 10 provided with a first layer 21 including a metal and a second layer 22 including an insulating material is prepared.

The substrate 10 may be a silicon substrate, a gallium arsenide substrate, a silicon germanium substrate, a ceramic substrate, a quartz substrate, a glass substrate for displays, or a silicon on insulator (SOI) substrate. Also, although not shown in FIG. 1A, the substrate 10 may include a conductive pattern. The conductive pattern may be metal wiring or contact, a gate electrode of a transistor, source/drain electrodes of a transistor, or a diode.

The metal included in the first layer 21 may include copper (Cu), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (AI), zirconium (Zr), tungsten (W), ruthenium (Ru), iridium (Ir), rhodium (Rh), or any combination thereof.

For example, the first layer 21 may include copper or tungsten.

The insulating material included in the second layer 22 may include silicon oxide, silicon nitride, silicon oxynitride, a low-k (low-dielectric constant) material, or any combination thereof. The low-k material may be a material having a dielectric constant value of about 4 or less, and is not particularly limited as long as it is a corresponding material. According to an embodiment, the low-k material may include silicon (Si), carbon (C), oxygen (O) and hydrogen (H), and a multiplicity of nanometer-sized pores. According to an embodiment, the low-k material may include a fluorine-doped silicon dioxide, an organosilicate glass (e.g., carbon-doped oxide), and/or a spin-on organic polymeric dielectrics.

Subsequently, the composition as described in this specification is applied onto the first layer 21 (or the first layer 21 and the second layer 22) of FIG. 1A. The application of the composition may be performed by dipping, coating, or spraying.

Then, the composition is heat-treated to form a protection layer pattern 21P having an opening exposing a surface of the second layer 22, on a surface of the first layer 21.

According to an embodiment, the protection layer pattern 21P of FIG. 1B may be a SAM including a moiety represented by Formula 1A below.

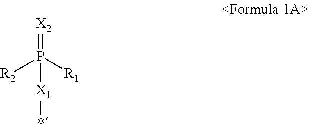

In Formula 1A,
X₁, X₂, R₁, and R₂ are as described in this specification, respectively, and
*′ is a bonding site (e.g., chemical bonding site) with a metal atom of the surface of the first layer 21.

FIG. 1B shows a protection layer pattern 21P including the moiety represented by Formula 1A in which both X₁ and X₂ are O.

In the case where the process of applying the composition to the first layer 21 (or the first layer 21 and the second layer 22) is performed by dipping, coating, or spraying, a trace amount of the first layer 21 is etched, resulting in generation of ions of the material included in the first layer 21, for example, metal ions.

Aggregated particles may be formed by aggregation between the generated metal ions and the protection layer-forming material that is not attached to the surface of the first layer 21. In the case where such aggregation is not effectively controlled and/or inhibited, there may be residual aggregated particles having a large particle size enough to prevent effective binding of the moiety represented by Formula 1A to the surface of the first layer 21 on the surface of the first layer 21, and/or residual aggregated particles having a large particle size enough to prevent a third layer-forming material 23 of FIG. 1C, described below, from being effectively applied onto the surface of the second layer 22 on the surface of the second layer 22.

However, the compound represented by Formula 1 does not substantially generate such residual aggregated particles having a large particle size enough to prevent effective binding of the moiety represented by Formula 1A to the surface of the first layer 21 on the surface of the first layer 21, and/or residual aggregated particles having a large particle size enough to prevent a third layer-forming material 23 of FIG. 1C, described below, from being effectively applied onto the surface of the second layer 22 on the surface of the second layer 22 (e.g., refer to Evaluation Example 2 described below). As a result, both the protection layer pattern 21P and the third layer pattern 23P may be precisely formed by using the composition as described in the specification.

The process of heat treating the composition for formation of the protection layer pattern 21P of FIG. 1B may be performed in a temperature range of about 100° C. to about 500° C., about 100° C. to about 400° C., about 200° C. to about 500° C., about 200° C. to about 400° C., about 250° C. to about 400° C., or about 300° C. to about 350° C., for example, for about 0.1 min to about 30 min, about 0.1 min to about 10 min, about 0.1 min to about 5 min, about 0.5 min to about 30 min, about 0.5 min to about 10 min, or about 0.5 min to about 5 min. By performing the heat treatment under to conditions described above, the solvent included in the composition may be effectively removed, and the bonding between the moiety represented by Formula 1A and the metal atom of the surface of the first layer 21 may further be strengthened.

According to an embodiment, the protection layer pattern 21P may include the moiety represented by Formula 1A and the moiety represented by Formula 1A may be bound to the surface of the first layer 21, but may not be bound to the surface of the second layer 22 as a result of performing the process of applying the composition onto the first layer 21 (or the first layer 21 and the second layer 22) and the process of heat treating the composition. That is, by applying the composition onto the first layer 21 and the second layer 22 and performing heat treatment, the protection layer including the moiety represented by Formula 1A may automatically be formed, selectively, only on the surface of the first layer 21. This is a result of using the protection layer-forming material including the compound represented by Formula 1 described in the specification. Accordingly, the fine protection layer pattern 21P as shown in FIG. 1B may be formed by a simple wet method such as application of the composition and heat treatment at low cost without using expensive equipment such as a vacuum chamber.

Subsequently, as shown in FIG. 1C, a third layer pattern-forming material 23 is applied to onto the first layer 21 on which the protection layer pattern 21P is formed and the second layer 22. For descriptions of the third layer pattern-forming material, refer to descriptions of a material included in a third layer pattern 23P which will be described below.

The application of the third layer pattern-forming material 23 may be performed by atomic layer deposition (ALD), chemical vapor deposition (CVD), or the like.

In the moiety represented by Formula 1A included in the protection layer pattern 21P, R₁ is bound to R₂ via *—P(═O)—*′ therebetween, and the moiety of Formula 1A is bound to the metal atom of the surface of the first layer 21 via O or S of Formula 1A, so that the protection layer pattern 21P may have improved or excellent thermal stability (for example, refer to Evaluation Example 1 described below). Therefore, even when the protection layer pattern 21P is exposed to a high temperature for application of the third layer pattern-forming material 23, degradation of the material included in the protection layer pattern 21P and/or detachment of the protection layer pattern 21P from the first layer 21 may not occur.

Also, in Formula 1A included in the protection layer pattern 21P, R₁ and R₂ are each independently a C₁-C₃₀ alkyl group, a C₂-C₃₀ alkenyl group, etc., and thus the surface of the protection layer pattern 21P may have hydrophobicity (for example, refer to Evaluation Example 1 described below). As a result, a thickness of the third layer pattern-forming material 23 on the surface of the protection layer pattern 21P may be smaller than a thickness of the third layer pattern-forming material 23 on the surface of the second layer 22, so that a process of removing the protection layer pattern 21P, which will be described below with reference to FIG. 1D, may be easily performed, resulting in effective exposure of the surface of the first layer 21. Although the third layer pattern-forming material 23 is deposited on a portion of the surface of the protection layer pattern 21P, various modifications may be possible, for example, the third layer pattern-forming material 23 may not be deposited on the surface of the protection layer pattern 21P.

Subsequently, as shown in FIG. 1D, the protection layer pattern 21P is removed to form a third layer pattern 23P having an opening exposing the surface of the first layer 21, on the surface of the second layer 22.

The third layer pattern 23P may include titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), or any combination thereof.

As a result of removing the protection layer pattern 21P, the surface of the first layer 21 may be exposed. The removal of the protection layer pattern 21P may be performed by hydrogen plasma treatment.

Subsequently, as shown in FIG. 1E, a fourth layer 24 is applied onto the third layer pattern 23P and the surface of the first layer 21.

The fourth layer may include copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (AI), zirconium (Zr), tungsten (W), ruthenium (Ru), iridium (Ir), rhodium (Rh), or any combination thereof.

As described above, by selectively forming the protection layer pattern 21P only on the surface of the first layer 21 by using the composition described in the specification, a fine pattern including the protection layer pattern 21P and/or a fine pattern in which the first layer 21 is in electrical contact with the fourth layer 24 may precisely be formed at low cost.

### Method of Manufacturing Semiconductor Device

The composition may be effectively used in a method of manufacturing a semiconductor device.

Hereinafter, a method of manufacturing a semiconductor device using the composition according to an embodiment will be described with reference to FIGS. 2A to 2E.

The semiconductor device, as shown in FIG. 2E, may include:
a substrate 100;
an interlayer insulating layer 122 disposed on the substrate 100;
a via trench T1 formed inside the interlayer insulating layer 122;
a via 121 disposed inside the via trench T1;
a wiring trench T2 formed inside the interlayer insulating layer 122 and on the via 121; and
a wiring pattern 125 disposed inside the wiring trench T2, wherein the wiring pattern 125 includes a wiring barrier layer pattern 123P and a wiring filling layer 124 disposed on the wiring barrier layer pattern 123P.

First, as shown in FIG. 2A, a substrate 10 provided with an interlayer insulating layer 122, a via trench T1, a via 121, and a wiring trench T2 is prepared. As shown in FIG. 2A, inner walls of the wiring trench T2 may be defined by a surface of the via 121 and surfaces of the interlayer insulating layer 122.

For description of the substrate 100, the via 121, and the interlayer insulating layer 122 of FIG. 2A, refer to descriptions of the substrate 10, the first layer 21, and the second layer 22 of FIG. 1, respectively.

Subsequently, the composition as described in this specification is applied into the wiring trench T2 of FIG. 2A. For descriptions of the application of the composition into the wiring trench T2, refer to the descriptions of the process of applying the composition onto the first layer 21 (or the first layer 21 and the second layer 22) in FIG. 1A.

Then, the composition is heat-treated to form a protection layer pattern 121P having an opening exposing a surface of the interlayer insulating layer 122 on a surface of the via 121.

According to an embodiment, the protection layer pattern 121P of FIG. 2B may be a SAM including a moiety represented by Formula 1A below.

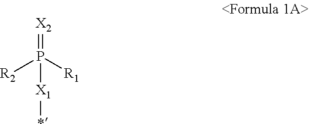

In Formula 1A,
X₁, X₂, R₁, and R₂ are as described in this specification, respectively, and
*′ is a bonding site (e.g., chemical bonding site) with a metal atom of the surface of the via 121.

For descriptions of the heat treatment of the composition and the protection layer pattern 121P of FIG. 2B, refer to the descriptions of the heat treatment of the composition and the protection layer pattern 21P of FIG. 1B, respectively.

The compound represented by Formula 1 described in the specification does not substantially generate residual aggregated particles having a large particle size enough to prevent effective binding of the moiety represented by Formula 1A to the surface of the via 121 on the surface of the via 121, and/or residual aggregated particles having a large particle size enough to prevent a wiring barrier layer pattern-forming material 123 of FIG. 2C, described below, from being effectively applied onto the surface of the interlayer insulating layer 122 on the surface of the interlayer insulating layer 122. Therefore, both the protection layer pattern 121P and the wiring barrier layer pattern 123P may be precisely formed by using the composition as described in the specification.

According to an embodiment, the protection layer pattern 121P may include the moiety represented by Formula 1A and the moiety represented by Formula 1A may be bound to the surface of the via 121, but may not be bound to the surface of the interlayer insulating layer 122 as a result of performing the process of applying the composition into the wiring trench T2, i.e., onto the via 121 and the interlayer insulating layer 122, and the process of heat treating the composition. That is, by applying the composition into the wiring trench T2 and performing heat treatment, the protection layer including the moiety represented by Formula 1A may automatically be formed, selectively, only on the surface of the via 121. This is a result of using the protection layer-forming material including the compound represented by Formula 1 described in the specification. Accordingly, the fine protection layer pattern 121P as shown in FIG. 2B may be formed by a simple wet method such as application of the composition and heat treatment at low cost without using expensive equipment such as a vacuum chamber.

Subsequently, as shown in FIG. 2C, a wiring barrier layer pattern-forming material 123 is applied into the wiring trench T2 on which the protection layer pattern 121P is formed, i.e., onto the via 121, and the interlayer insulating layer 122.

For descriptions of the wiring barrier layer pattern-forming material 123 of FIG. 2C and the process of applying the same, refer to the descriptions of the third layer pattern-forming material of FIG. 1C and the process of applying the same.

In the moiety represented by Formula 1A included in the protection layer pattern 121P, R₁ is bound to R₂ via *—P(═O)—*′ therebetween, and the moiety of Formula 1A is bound to the metal atom of the surface of the via 121 via O or S of Formula 1A, so that the protection layer pattern 121P may have improved or excellent thermal stability. Therefore, even when the protection layer pattern 121P is exposed to a high temperature for application of the wiring barrier layer pattern-forming material 123, degradation of the material included in the protection layer pattern 121P and/or detachment of the protection layer pattern 121P from the via 121 may not occur.

Also, in Formula 1A included in the protection layer pattern 121P, R₁ and R₂ are each independently a C₁-C₃₀ alkyl group, a C₂-C₃₀ alkenyl group, etc., and thus the surface of the protection layer pattern 121P may have hydrophobicity. As a result, a thickness of the wiring barrier layer pattern-forming material 123 on the surface of the protection layer pattern 121P may be smaller than a thickness of the wiring barrier layer pattern-forming material 123 on the surface of the interlayer insulating layer 122, so that a process of removing the protection layer pattern 121P, which will be described below with reference to FIG. 2D, may be easily performed, resulting in effective exposure of the surface of the via 121. Although the wiring barrier layer pattern-forming material 123 is not deposited on the surface of the protection layer pattern 121P of FIG. 2C, various modifications may be possible, for example, the wiring barrier layer pattern-forming material 123 may be deposited on a portion of the surface of the protection layer pattern 21P.

Subsequently, as shown in FIG. 2D, the protection layer pattern 121P is removed to form a wiring barrier layer pattern 123P having an opening exposing the surface of the via 121, on the surface of the interlayer insulating layer 122.

For descriptions of the wiring barrier layer pattern 123P and the removal of the protection layer pattern 121P of FIG. 2D, refer to the descriptions of the third layer pattern 23P and the removal of the protection layer pattern 21P of FIG. 1D, respectively.

Then, as shown in FIG. 2E, the wiring filling layer 124 is applied onto the surfaces of the wiring barrier layer pattern 123P and the via 121 in the wiring trench T2 to form the wiring pattern 125.

For descriptions of the wiring filling layer 124 shown in FIG. 2E, refer to the descriptions of the fourth layer 24 of FIG. 1E.

As described above, by forming the protection layer pattern 121P by using the composition described in the specification, the wiring pattern 125 may be formed precisely at low cost.

### Method of Forming Protection Layer

The composition may be effectively used for forming a protection layer.

According to another embodiment, a method of forming a protection layer may include:
preparing a substrate on which is provided a metal layer;
applying the composition as described in the specification onto the metal layer; and

Heat treating the composition to form a protection layer on the surface of the metal layer.

For the descriptions of the substrate and the metal layer, refer to the descriptions of the substrate 10 and the first layer 21 of FIG. 1A, respectively.

For the descriptions of the process of applying the composition onto the metal layer, refer to the descriptions of the process of applying the composition onto the first layer 21 (or the first layer 21 and the second layer 22) in FIG. 1A.

For the descriptions of the process of heat treating the composition, refer to the descriptions of the process of heat treating the composition in FIG. 1B.

For the descriptions of the protection layer, refer to the descriptions of the protection layer pattern 21P of FIG. 1B.

### Examples 1 and 2 and Comparative Examples C1 to C5

20 wt % of water, ethylene glycol weighed in an amount selected from a range of 71.6 wt % to 71.89 wt %, 8 wt % of sulfolane, tetramethylammonium hydroxide (TMAH) weighed in an amount selected from a range of 0.01 wt % to 0.3 wt %, and 0.1 wt % of a protection layer-forming material shown in Table 1 were mixed to prepare compositions of Examples 1 and 2 and Comparative Examples C1 to C5. In each composition, the amounts of ethylene glycol and TMAH were selected such that the pH of the composition is adjusted to 7.5.

### Comparative Example C6

A composition of Comparative Example C6 was prepared by mixing 20 wt % of water, 71.9 wt % of ethylene glycol, 8 wt % of sulfolane, and 0.1 wt % of TMAH.

### Evaluation Example 1

The pH of the composition of Example 1 was evaluated using a pH meter and occurrence of phase separation in the composition was visually evaluated, and the results are shown in Table 1.

The composition of Example 1 was placed in a beaker and heated to 60° C. A copper (Cu) film specimen with a size of 1 cm×1 cm was immersed in the beaker for 1 minute. Then, the Cu film specimen was heat-treated at 300° C. for 1 minute, and a water contact angle of the heat-treated Cu film specimen was evaluated by using a contact angle meter, and the results are shown in Table 1.

The test was repeated on the compositions of Example 2 and Comparative Examples C1 to C6, and the results are shown in Table 1.

TABLE 1

| | Protection | | | | Water |
|---|---|---|---|---|---|
| | layer- | | | | contact |
| | forming | | | Occurrence | angle of |
| | material | Amount | | of phase | heat-treated |
| Category | Material | (wt %) | pH | separation | Cu film (*) |
| Example 1 | 1a | 0.1 | 7.5 | N | 90 |
| Example 2 | 2a | 0.1 | 7.5 | N | 88 |
| Comparative | C1 | 0.1 | 7.5 | N | 75 |
| Example | | | | | |
| C1 | | | | | |
| Comparative | C2 | 0.1 | 7.5 | N | 93 |
| Example | | | | | |
| C2 | | | | | |
| Comparative | C3 | 0.1 | 7.5 | Y | 43 |
| Example | | | | | |
| C3 | | | | | |
| Comparative | C4 | 0.1 | 7.5 | N | 48 |
| Example | | | | | |
| C4 | | | | | |
| Comparative | C5 | 0.1 | 7.5 | N | 40 |
| Example | | | | | |
| C5 | | | | | |
| Comparative | — | — | 7.5 | N | 38 |
| Example | | | | | |
| C6 | | | | | |

Phase separation occurrence “N”: No phase separation was observed in the composition.

Phase separation occurrence “Y”: Phase separation was observed in the composition.

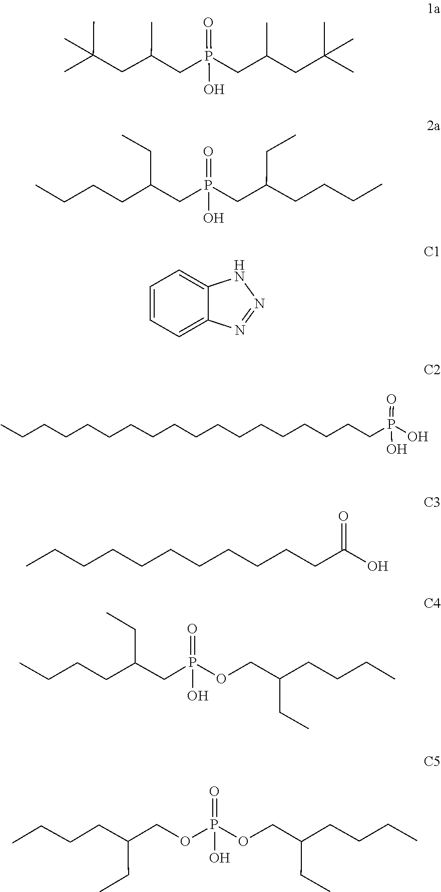

From Table 1, because the water contact angles of the Cu films respectively immersed in the compositions of Comparative Examples C3 to C5 and heat-treated are similar to the water contact angles of the Cu film immersed in the composition of Comparative Example C6 without the protection layer-forming material, it may be confirmed that the protection layer-forming materials included in the compositions of Comparative Examples C3 to C5 cannot substantially provide hydrophobic protection layers onto the surfaces of the Cu films. Although not limited to any particular theory, the protection layer-forming materials respectively included in the compositions of Comparative Examples C3 to C5 may have i) failed to effectively bind to the surface of the Cu films during the immersing process in the composition, and/or ii) detached from the surface of the Cu films during the process of heat treating the composition.

Meanwhile, from Table 1, because the water contact angles of the Cu films respectively immersed in the compositions of Examples 1 and 2 and Comparative Examples C1 and C2 and heat-treated were about twice or more that of the Cu film immersed in the composition of Comparative Example C6 without the protection layer-forming material and heat-treated, it may be confirmed that the protection layer-forming materials included in the compositions of Examples 1 and 2 and Comparative Examples C1 and C2 may substantially provide hydrophobic protection layers having improved or excellent thermal stability on the surfaces of the Cu films.

Subsequently, the compositions of Examples 1 and 2 and Comparative Examples C1 and C2 were evaluated according to Evaluation Example 2 below.

### Evaluation Example 2

The composition of Example 1 was placed in a beaker and heated to 60° C. and 100 ppm of a CuSO₄ solution in water was added to the beaker to supply copper ions into the composition of Example 1. After 1 hour, a dynamic light scattering (DLS) size of particles generated in the beaker by the copper ions was evaluated using a DLS diameter by extracting intensity distribution data, and the results are shown in Table 2.

The test was repeated on the compositions of Example 2 and Comparative Examples C1 to C2, and the results are shown in Table 2.

TAABLE 2

| | Protection layer- | | |
|---|---|---|---|
| | forming material | | |
| | | Amount | DLS size |
| Category | Material | (wt %) | (nm) |
| Example 1 | 1a | 0.1 | 105 |
| Example 2 | 2a | 0.1 | 97 |
| Comparative | C1 | 0.1 | 1206 |
| Example C1 | | | |
| Comparative | C2 | 0.1 | 820 |
| Example C2 | | | |

From Table 2, it may be confirmed that the DLS size of aggregated particles generated by aggregation between each of the protection layer-forming materials included in the compositions of Examples 1 and 2 and the copper ions is smaller than the DLS size of aggregated particles generated by aggregation between each of the protection layer-forming materials included in the compositions of Comparative Examples C1 and C2 and copper ions.

Based thereon, it may be confirmed that by using the protection layer-forming materials respectively included in the compositions of Examples 1 and 2, aggregation between copper ions and the protection layer-forming materials which may be generated in the case of using the compositions of Examples 1 and 2 may be effectively controlled and/or suppressed, so that residual aggregated particles impairing the accuracy of the fine pattern formation process may be reduced or minimized.

By using the composition, the protection layer having improved or excellent thermal stability and/or hydrophobicity may be selectively formed on the surface of a particular material without generating relatively large residual aggregated particles, and therefore the fine pattern may be precisely formed by using the composition at low cost. By using the composition, a high-quality semiconductor device may be cost-effectively manufactured.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A composition comprising:
a solvent; and
a protection layer-forming material,
wherein the protection layer-forming material comprises a compound represented by Formula 1 below, 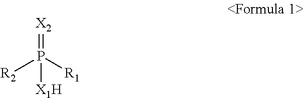
wherein in Formula 1,
X₁ and X₂ are each independently O or S,
R₁ and R₂ are each independently a C₁-C₃₀ alkyl group, a C₂-C₃₀ alkenyl group, a C₃-C₁₀ cycloalkyl group, a C₂-C₁₀ heterocycloalkyl group, a C₆-C₃₀ aryl group, or a C₂-C₃₀ heteroaryl group,
wherein, in R₁ and R₂, at least one hydrogen is optionally substituted with a halogen atom, a C₁-C₃₀ alkyl group, *—O(Q₁), *—NH₂, *—NH(Q₁), or *—N(Q₁)(Q₂),
wherein Q₁ and Q₂ are each independently a C₁-C₃₀ alkyl group, or a C₆-C₃₀ aryl group, wherein, in Q₁ and Q₂, at least one hydrogen is optionally substituted with a halogen atom, a C₁-C₃₀ alkyl group, a C₁-C₃₀ alkoxy group, an amino group, a (C₁-C₁₀ alkyl)amino group, or a di(C₁-C₁₀ alkyl)amino group, and
* is a bonding site with a neighboring atom.

2. The composition of claim 1, wherein the composition does not comprise an oxidant.

3. The composition of claim 1, wherein the solvent comprises a compound with a dielectric constant of 15 or more.

4. The composition of claim 1, wherein the solvent comprises water, a water-miscible compound, or any combination thereof.

5. The composition of claim 1, wherein
in Formula 1, R₁ and R₂ are each independently a C₁-C₂₀ alkyl group, a C₂-C₂₀ alkenyl group, a C₅-C₇ cycloalkyl group, a C₃-C₄ heterocycloalkyl group, a C₆-C₁₀ aryl group, or a C₂-C₁₀ heteroaryl group,
in R₁ and R₂, at least one hydrogen is optionally substituted with a C₁-C₁₀ alkyl group, *—O(Q₁), *—NH₂, *—NH(Q₁), or *—N(Q₁)(Q₂),
Q₁ and Q₂ are each independently a C₁-C₁₀ alkyl group, or a C₆-C₁₀ aryl group, and
in Q₁ and Q₂, at least one hydrogen is optionally substituted with a halogen atom, a C₁-C₁₀ alkyl group, a C₁-C₁₀ alkoxy group, an amino group, a (C₁-C₁₀ alkyl)amino group, or a di(C₁-C₁₀ alkyl)amino group.

6. The composition of claim 1, wherein in Formula 1, R₁ and R₂ are each independently a branched C₃-C₃₀ alkyl group.

7. The composition of claim 1, wherein
the protection layer-forming material further comprises a compound represented by Formula 2 below: 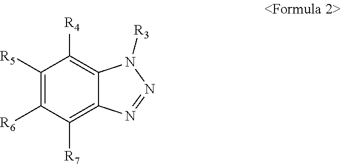
wherein, in Formula 2, R₃ to R₇ are each independently hydrogen, a hydroxyl group, an amino group, a nitro group, a C₁-C₃₀ alkoxy group, a C₁-C₃₀ alkyl group, a C₂-C₃₀ alkenyl group, a C₆-C₃₀ aryl group, or a C₂-C₃₀ heteroaryl group.

8. The composition of claim 1, wherein an amount of the protection layer-forming material is about 0.001 wt % to about 10 wt % based on 100 wt % of the composition.

9. The composition of claim 1, wherein the composition has a pH of about 5 to about 10.

10. A method of preparing a fine pattern, the method comprising:
preparing a substrate having a first layer and a second layer on the substrate, wherein the first layer includes a metal, and the second layer includes an insulating material;
applying a composition including a solvent and a protection layer-forming material onto the first layer, wherein the protection layer-forming material comprises a compound represented by Formula 1 below; and
heat treating the composition to form a protection layer pattern on a surface of the first layer, the protection layer pattern exposing a surface of the second layer, 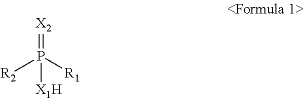
wherein in Formula 1,
X₁ and X₂ are each independently O or S,
R₁ and R₂ are each independently a C₁-C₃₀ alkyl group, a C₂-C₃₀ alkenyl group, a C₃-C₁₀ cycloalkyl group, a C₂-C₁₀ heterocycloalkyl group, a C₆-C₃₀ aryl group, or a C₂-C₃₀ heteroaryl group,
wherein, in R₁ and R₂, at least one hydrogen is optionally substituted with a halogen atom, a C₁-C₃₀ alkyl group, *—O(Q₁), *—NH₂, *—NH(Q₁), or *—N(Q₁)(Q₂),
wherein Q₁ and Q₂ are each independently a C₁-C₃₀ alkyl group, or a C₆-C₃₀ aryl group,
wherein, in Q₁ and Q₂, at least one hydrogen is optionally substituted with a halogen atom, a C₁-C₃₀ alkyl group, a C₁-C₃₀ alkoxy group, an amino group, a (C₁-C₁₀ alkyl)amino group, or a di(C₁-C₁₀ alkyl)amino group, and
* is a bonding site with a neighboring atom.

11. The method of claim 10, wherein the metal included in the first layer comprises copper (Cu), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), zirconium (Zr), tungsten (W), ruthenium (Ru), iridium (Ir), rhodium (Rh), or any combination thereof.

12. The method of claim 10, wherein the insulating material included in the second layer comprises silicon oxide, silicon nitride, silicon oxynitride, a low-k material, or any combination thereof.

13. The method of claim 10, wherein the applying the composition onto the first layer is performed by dipping, coating, or spraying.

14. The method of claim 10, wherein the heat treating the composition is performed in a temperature range of about 100° C. to about 500° C.

15. The method of claim 10, wherein
the protection layer pattern comprises a moiety represented by Formula 1A below, and
as a result of performing the applying the composition onto the first layer and the heat treating of the composition, the moiety represented by Formula 1A below binds to the surface of the first layer but does not bind to the surface of the second layer, 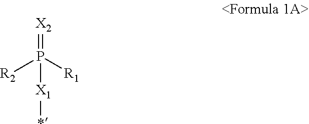
wherein, in Formula 1A,
X₁ and X₂ are each independently O or S, and
R₁ and R₂ are each independently a C₁-C₃₀ alkyl group, a C₂-C₃₀ alkenyl group, a C₃-C₁₀ cycloalkyl group, a C₂-C₁₀ heterocycloalkyl group, a C₆-C₃₀ aryl group, or a C₂-C₃₀ heteroaryl group,
wherein, in R₁ and R₂ of Formula 1A, at least one hydrogen is optionally substituted with a halogen atom, a C₁-C₃₀ alkyl group, *—O(Q₁), *—NH₂, *—NH(Q₁), or *—N(Q₁)(Q₂),
wherein Q₁ and Q₂ are each independently a C₁-C₃₀ alkyl group, or a C₆-C₃₀ aryl group,
wherein, in Q₁ and Q₂, at least one hydrogen is optionally substituted with a halogen atom, a C₁-C₃₀ alkyl group, a C₁-C₃₀ alkoxy group, an amino group, a (C₁-C₁₀ alkyl)amino group, or a di(C₁-C₁₀ alkyl)amino group,
* is a bonding site with a neighboring atom, and
*′ is a bonding site with a metal atom of the surface of the first layer.

16. The method of claim 10, further comprising:
applying a third layer pattern-forming material onto the first layer on which the protection layer pattern is formed and the second layer;
removing the protection layer pattern to form a third layer pattern on the surface of the second layer, the third layer pattern having an opening exposing the surface of the first layer; and
applying a fourth layer onto a surface of the third layer pattern and the surface of the first layer.

17. The method of claim 16, wherein the third layer pattern comprises titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), or any combination thereof.

18. The method of claim 16, wherein the fourth layer comprises copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), zirconium (Zr), tungsten (W), ruthenium (Ru), iridium (Ir), rhodium (Rh), or any combination thereof.

19. A method of manufacturing a semiconductor device, the method comprising:
providing a substrate including an interlayer insulating layer on the substrate and a via in a via trench defined by the interlayer insulating layer, the interlayer insulating layer defining a wiring trench over the via trench and exposing the via in the via trench, a surface of the via being in fluid communication with the wiring trench;
applying a composition into the wiring trench, the composition including a solvent and a protection layer-forming material, wherein the protection layer-forming material comprises a compound represented by Formula 1 below;
heat treating the composition to form a protection layer pattern on the surface of the via, the protection layer pattern exposing a surface of the interlayer insulating layer, the protection layer pattern being formed in the wiring trench;
applying a wiring barrier layer pattern-forming material into the wiring trench;
removing the protection layer pattern to form a wiring barrier layer pattern on the surface of the interlayer insulating layer, the wiring barrier layer pattern including an opening that exposes the surface of the via, and
forming a wiring pattern by applying a wiring filling layer onto the surface of the wiring barrier layer pattern and the surface of the via, the wiring pattern being inside the wiring trench, 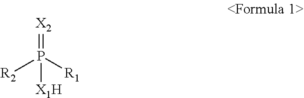
wherein, in Formula 1,
X₁ and X₂ are each independently O or S, and
R₁ and R₂ are each independently a C₁-C₃₀ alkyl group, a C₂-C₃₀ alkenyl group, a C₃-C₁₀ cycloalkyl group, a C₂-C₁₀ heterocycloalkyl group, a C₆-C₃₀ aryl group, or a C₂-C₃₀ heteroaryl group,
wherein, in R₁ and R₂, at least one hydrogen is optionally substituted with a halogen atom, a C₁-C₃₀ alkyl group, *—O(Q₁), *—NH₂, *—NH(Q₁), or *—N(Q₁)(Q₂),
wherein Q₁ and Q₂ are each independently a C₁-C₃₀ alkyl group, or a C₆-C₃₀ aryl group,
wherein, in Q₁ and Q₂, at least one hydrogen is optionally substituted with a halogen atom, a C₁-C₃₀ alkyl group, a C₁-C₃₀ alkoxy group, an amino group, a (C₁-C₁₀ alkyl)amino group, or a di(C₁-C₁₀ alkyl)amino group, and
* is a bonding site with a neighboring atom.

20. The method of claim 19, wherein
the protection layer pattern comprises a moiety represented by Formula 1A below, the via comprises copper (Cu), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), zirconium (Zr), tungsten (W), ruthenium (Ru), iridium (Ir), rhodium (Rh), or any combination thereof,
the interlayer insulating layer comprises silicon oxide, silicon nitride, silicon oxynitride, a low-k material, or any combination thereof, and
as a result of performing the applying the composition into the wiring trench and the heat treating the composition, the moiety represented by Formula 1A below binds to the surface of the via in the wiring trench but does not bind to the surface of the interlayer insulating layer in the wiring trench, 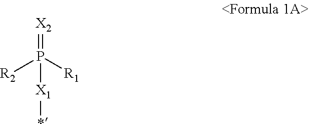
wherein, in Formula 1A,
X₁ and X₂ are each independently O or S, and
R₁ and R₂ are each independently a C₁-C₃₀ alkyl group, a C₂-C₃₀ alkenyl group, a C₃-C₁₀ cycloalkyl group, a C₂-C₁₀ heterocycloalkyl group, a C₆-C₃₀ aryl group, or a C₂-C₃₀ heteroaryl group,
in R₁ and R₂ of Formula 1A, at least one hydrogen is optionally substituted with a halogen atom, a C₁-C₃₀ alkyl group, *—O(Q₁), *—NH₂, *—NH(Q₁), or *—N(Q₁)(Q₂),
wherein Q₁ and Q₂ are each independently a C₁-C₃₀ alkyl group or a C₆-C₃₀ aryl group,
wherein, in Q₁ and Q₂, at least one hydrogen is optionally substituted with a halogen atom, a C₁-C₃₀ alkyl group, a C₁-C₃₀ alkoxy group, an amino group, a (C₁-C₁₀ alkyl)amino group, or a di(C₁-C₁₀ alkyl)amino group,
* is a binding site with a neighboring atom, and
*′ is a binding site with a metal atom of the surface of the via.
